(19) United States
(12) Patent Application Publication
(10) Pub. No.: US 2026/0094653 A1
(43) Pub. Date: Apr. 2, 2026

(54) MEMORY DEVICE FOR PERFORMING ERASE OPERATION AND OPERATING METHOD OF THE MEMORY DEVICE

(71) Applicant: SK hynix Inc., Gyeonggi-do (KR)

(72) Inventors: Mu Sun KIM, Gyeonggi-do (KR); Sung Hwa HONG, Gyeonggi-do (KR); Seung Il KIM, Gyeonggi-do (KR); Yong Ho KIM, Gyeonggi-do (KR); Byoung Jun PARK, Gyeonggi-do (KR); Joo Hyun PARK, Gyeonggi-do (KR)

(21) Appl. No.: 19/084,777

(22) Filed: Mar. 20, 2025

(30) Foreign Application Priority Data
Sep. 27, 2024 (KR) 10-2024-0131883

(51) Int. Cl. G11C 16/34; G11C 16/04; G11C 16/24

(52) U.S. Cl. CPC G11C 16/3445; G11C 16/0483; G11C 16/24

(57) ABSTRACT

A memory device includes a memory block including memory cells arranged corresponding to bit lines and word lines, a peripheral circuit configured to perform an erase operation of erasing data stored in the memory cells, and an erase operation controller configured to apply an erase verify voltage to the word lines during the erase operation, and determine whether the erase operation is completed based on a result of comparing a predetermined reference count with a fail bit count, the fail bit count corresponding to a number of bit lines coupled to one or more memory cells having threshold voltages greater than the erase verify voltage, wherein the predetermined reference count is a sum of a predetermined reference value and a number of masking fail columns in which a masking operation fails among the bit lines.

### CROSS-REFERENCE TO RELATED APPLICATION

The present application claims priority under 35 U.S.C. § 119(a) to Korean patent application number 10-2024-0131883 filed on Sep. 27, 2024, the entire disclosure of which is incorporated by reference herein.

### BACKGROUND

### 1. Technical Field

Various embodiments of the present disclosure relate generally to a memory device and an operating method of the memory device, and more particularly, to a memory device that performs an erase operation and a method of operating the memory device.

### 2. Related Art

Memory devices may be divided into volatile memory devices and non-volatile memory devices.

A volatile memory device may retain data as long as power is being supplied, and may lose the stored data in the absence of power supply. Types of volatile memory devices may include Static Random Access Memory (SRAM), Dynamic Random Access Memory (DRAM), and the like.

A non-volatile memory device may not lose data even in the absence of power supply. Types of non-volatile memory devices may include Read Only Memory (ROM), Programmable ROM (PROM), Electrically Programmable ROM (EPROM), Electrically Erasable and Programmable ROM (EEPROM), flash memory, and the like.

### SUMMARY

Embodiments of the present disclosure provide a memory device that performs an erase operation and a method of operating the memory device.

According to an embodiment of the present disclosure, a memory device may include a memory block including memory cells arranged corresponding to bit lines and word lines, a peripheral circuit configured to perform an erase operation of erasing data stored in the memory cells, and an erase operation controller configured to apply an erase verify voltage to the word lines during the erase operation, and determine whether the erase operation is completed based on a result of comparing a predetermined reference count with a fail bit count, the fail bit count corresponding to a number of bit lines coupled to one or more memory cells having threshold voltages greater than the erase verify voltage, wherein the predetermined reference count is a sum of a predetermined reference value and a number of masking fail columns in which a masking operation fails among the bit lines.

According to an embodiment of the present disclosure, a memory device may include a cell string including memory cells coupled in series and coupled to word lines, respectively; a page buffer including latches coupled to the cell string through a bit line; and a page buffer controller configured to control the page buffer to input a masking bit to an input/output latch among the latches and perform a data transfer operation by moving the masking bit to other latches except the input/output latch, among the latches.

According to an embodiment of the present disclosure, a method of operating a memory device including a page buffer including an input/output latch, a transfer latch, and a sensing latch, may include inputting a masking bit to the input/output latch, moving a value input to the input/output latch, to the transfer latch, moving the value moved to the transfer latch, to the sensing latch, moving the value moved to the sensing latch, back to the input/output latch, outputting the value moved back to the input/output latch, and determining a bit line coupled to the page buffer as a masking fail column, based on a result of comparing an output value with the masking bit.

### BRIEF DESCRIPTION OF THE DRAWINGS

FIG. 1 is a diagram illustrating a configuration of a data storage device including a memory device according to an embodiment of the present disclosure;

FIG. 2 is a diagram illustrating a detailed configuration of a memory device shown in FIG. 1, according to an embodiment of the present disclosure;

FIG. 3 is a diagram illustrating a detailed configuration of a memory block shown in FIG. 2, according to an embodiment of the present disclosure;

FIG. 4 is a diagram illustrating a detailed configuration of an erase operation controller shown in FIG. 2, according to an embodiment of the present disclosure;

FIG. 5 is a diagram illustrating a threshold voltage distribution of memory cells during an erase operation, according to an embodiment of the present disclosure;

FIG. 6 is a diagram for describing an erase operation, according to an embodiment of the present disclosure;

FIG. 7 is a diagram illustrating a detailed configuration of one of page buffers included in a page buffer group shown in FIG. 2, according to an embodiment of the present disclosure;

FIG. 8 is a flowchart for describing a masking operation of a bad column, according to an embodiment of the present disclosure;

FIG. 9 is a flowchart for describing a method of detecting a masking fail column, according to an embodiment of the present disclosure;

FIG. 10 is a diagram illustrating a detailed configuration of a controller shown in FIG. 1, according to an embodiment of the present disclosure; and

FIG. 11 is a block diagram illustrating a configuration of a user system including a data storage device, according to an embodiment of the present disclosure.

### DETAILED DESCRIPTION

Specific structural or functional descriptions of embodiments in accordance with concepts which are disclosed in the present disclosure are illustrated only to describe the embodiments in accordance with the concepts and the embodiments in accordance with the concepts may be carried out by various forms but the descriptions are not limited to the embodiments described in the present disclosure.

Hereinafter, embodiments of the present disclosure will be described in detail with reference to the accompanying drawings in order for those skilled in the art to be able to implement the technical spirit of the present disclosure.

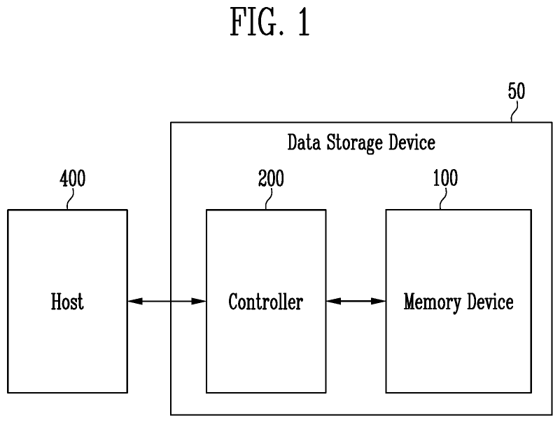

FIG. 1 is a diagram illustrating a configuration of a data storage device 50 including a memory device 100 according to an embodiment of the present disclosure.

Referring to FIG. 1, the data storage device 50 may include the memory device 100 and a controller 200. The data storage device 50 may store data in response to control of a host 400. Examples of the data storage device 50 may include a cellular phone, a smartphone, a laptop computer, a desktop computer, a game player, a smart TV, a tablet PC, or an in-vehicle infotainment system. According to an embodiment, the data storage device 50 may be controlled by the host 400 through wired/wireless communication for storing data in a remote location such as a server or a data center.

The data storage device 50 may interface with the host 400 through various types of communication methods. Based on an interfacing method, the data storage device 50 may be manufactured into various types of devices. For example, the data storage device 50 may be one of various types of storage devices such as a solid state drive (SSD), an embedded multimedia card (eMMC), a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, and a smart media card.

According to an embodiment, the data storage device 50 may be manufactured as one of various package types. For example, the data storage device 50 may be manufactured as one of package types such as Package-On-Package (POP), a System-In-Package (SIP), a System-On-Chip (SOC), a Multi-Chip Package (MCP), a Chip-On-Board (COB), a Wafer-level Fabricated Package (WFP), and a Wafer-level Stack Package (WSP).

The memory device 100 may store data. The memory device 100 may operate in response to control of the controller 200. The memory device 100 may include a plurality of memory cells which store data. Each of the memory cells may store a single data bit or a plurality of data bits.

Memory cells may be accessed in unit of a predetermined size determined depending on a type of a memory device. In addition, the memory cells may be accessed in different units depending on operations. For example, the memory cells are accessed in different size units depending on a program operation of storing data in the memory cells, a read operation of sensing the data stored in the memory cells, and an erase operation of erasing the data from the memory cells. For example, a program operation and a read operation may be performed in units of pages. An erase operation may be performed in units of memory blocks.

According to an embodiment, examples of the memory device 100 include Double Data Rate Synchronous Dynamic Random Access Memory (DDR SDRAM), Low Power Double Data Rate4 (LPDDR4) SDRAM, Graphics Double Data Rate (GDDR) SDRAM, Rambus Dynamic Random Access Memory (RDRAM), NAND flash memory, vertical NAND flash memory, NOR flash memory, resistive random access memory (RRAM), phase-change memory (PCM), magnetoresistive random access memory (MRAM), ferroelectric random access memory (FRAM), and spin transfer torque random access memory (STT-RAM).

The memory device 100 may receive a command and an address from the controller 200 and access an area selected by the received address in the memory cell array. The memory device 100 may perform an operation instructed by the command with respect to the area selected by the address. For example, the memory device 100 may perform a program operation, a read operation, and an erase operation. During a program operation, the memory device 100 may write data into an area selected by an address. During a read operation, the memory device 100 may sense the data from the selected area by the address. During an erase operation, the memory device 100 may erase the data stored in the selected area by the address.

The controller 200 may control general operations of the data storage device 50.

When power is applied to the data storage device 50, the controller 200 may execute firmware FW. The data storage device 50 may translate a logical address provided by the host 400 into a physical address which is used by the memory device 100. In the present disclosure, the term ‘logical address’ or ‘logical block address’ refers to an address which is provided by the host 400 for identifying data provided by the host 400, and the term ‘physical address’ or ‘physical block address’ refers to an address for locating a position at which data is stored within the memory device 100.

The controller 200 may control the memory device 100 to perform a program operation, a read operation, or an erase operation in response to a request from the host 400. During a program operation, the controller 200 may provide a program command, an address, and data to the memory device 100. During a read operation, the controller 200 may provide a read command and an address to the memory device 100. During an erase operation, the controller 200 may provide an erase command and an address to the memory device 100.

According to an embodiment, the controller 200 may include an error correction code (ECC) processor (not shown). Alternatively, the ECC processor may be included as a separate chip or device from the controller 200 in the data storage device 50. The ECC processor (not shown) may detect or correct errors included in data obtained by the read operation from the memory device 100. According to an embodiment, the number of bits which are correctable by the ECC processor may be limited.

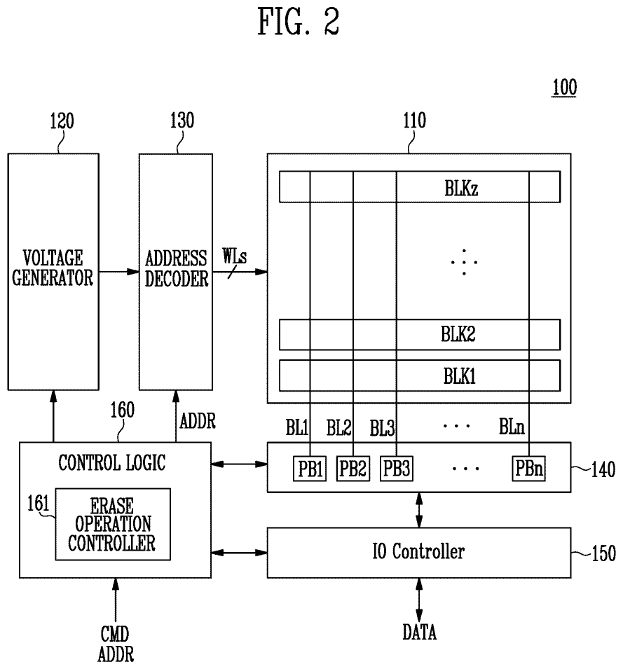

FIG. 2 is a diagram illustrating a detailed configuration of the memory device 100 shown in FIG. 1, according to an embodiment of the present disclosure.

Referring to FIG. 2, the memory device 100 may include a memory cell array 110, a voltage generator 120, an address decoder 130, a page buffer group 140, an input/output (IO) controller 150, and a control logic 160.

The memory cell array 110 may include a plurality of memory blocks BLK1 to BLKz. The plurality of memory blocks BLK1 to BLKz may be coupled to the address decoder 130 through word lines WLs. The plurality of memory blocks BLK1 to BLKz may be coupled to the page buffer group 140 through bit lines BL1 to BLn. Memory cells may be located at intersections between a word line corresponding to a row line and a bit line corresponding to a column line. Therefore, the memory cells may be in the form of an array which includes a plurality of rows and a plurality of columns.

Each of the plurality of memory blocks BLK1 to BLKz may include a plurality of memory cells. According to an embodiment, the plurality of memory cells may be non-volatile memory cells. Memory cells coupled to the same word line, among the plurality of memory cells, may be defined as a single physical page. A memory block may include a plurality of physical pages. Each of the memory cells may be programmed as a Single Level Cell (SLC) storing one data bit, a Multi-Level Cell (MLC) storing two data bits, a Triple Level Cell (TLC) storing three data bits, or a Quad Level Cell (QLC) storing four data bits.

According to an embodiment, the voltage generator 120, the address decoder 130, the page buffer group 140, and the input/output controller 150 may be collectively a peripheral circuit. The peripheral circuit may drive the memory cell array 110 in response to the control logic 160. The peripheral circuit may drive the memory cell array 110 to perform a program operation, a read operation, and an erase operation.

The voltage generator 120 may be configured to generate a plurality of operating voltages by using an external power voltage supplied to the memory device 100. The voltage generator 120 may be controlled by the control logic 160.

According to an embodiment, the voltage generator 120 may generate an internal power voltage by regulating an external power voltage. The internal power voltage generated by the voltage generator 120 may serve as an operating voltage of the memory device 100.

According to an embodiment, the voltage generator 120 may generate various operating voltages by using the external power voltage or the internal power voltage. The voltage generator 120 may generate various voltages required by the memory device 100. For example, the voltage generator 120 may generate a plurality of erase voltages, a plurality of program voltages, a plurality of pass voltages, and a plurality of read voltages.

According to an embodiment, the voltage generator 120 may include a plurality of pump circuits which receive an internal power voltage to generate a plurality of operating voltages with various voltage levels. The generated operating voltages may be supplied to the memory cell array 110 by the address decoder 130.

The address decoder 130 may be coupled to the memory cell array 110 through the word lines WLs. The address decoder 130 may operate in response to control of the control logic 160. The address decoder 130 may receive an address ADDR from the control logic 160. The address decoder 130 may decode the received address ADDR. The address decoder 130 may select one memory block among the memory blocks BLK1 to BLKz according to the decoded address. The address decoder 130 may select at least one word line among word lines of a selected memory block according to the decoded address. According to an embodiment, the address decoder 130 may couple the page buffer group 140 and the memory cell array 110 to each other according to the decoded address. According to an embodiment, the address decoder 130 includes components such as a row decoder, a column decoder, and an address buffer.

The page buffer group 140 may be coupled to the memory cell array 110 through the bit lines BL1 to BLn. The bit lines BL1 to BLn may be coupled to a plurality of page buffers PB1 to PBn, respectively.

During a program operation, data may be stored in selected memory cells according to data stored in the plurality of page buffers PB1 to PBn. During a read operation, the data stored in the selected memory cells may be sensed through the bit lines BL1 to BLn, and the sensing data may be stored in the plurality of page buffers PB1 to PBn. During an erase operation, data stored in a selected memory block may be erased in response to control signals provided to the plurality of page buffers PB1 to PBn.

The input/output controller 150 may communicate with an external device. The input/output controller 150 may communicate with the controller 200 as described above with reference to FIG. 1. During a program operation, the input/output controller 150 may receive data to be stored in the memory device 100 from the controller 200. The input/output controller 150 may provide data stored in the plurality of page buffers PB1 to PBn during a read operation.

The control logic 160 may control the voltage generator 120, the address decoder 130, the page buffer group 140, and the input/output controller 150. The control logic 160 may operate in response to a command CMD transferred from an external device. The control logic 160 may control the peripheral circuit by generating control signals in response to the command CMD and the address ADDR.

According to an embodiment, the control logic 160 includes an erase operation controller 161.

The erase operation controller 161 may control the peripheral circuit to perform an erase operation of erasing the data stored in the selected memory block in response to an erase command provided by the controller 200.

The erase operation may be performed before a program operation is performed to store data in a memory block. Memory cells included in the memory block may be erased before the data is programmed into the memory cells. During an erase operation, threshold voltages of the memory cells included in the memory block may be reduced to fall within a threshold voltage range corresponding to an erase state.

An erase operation may be performed in units of memory blocks. The erase operation may include one or more erase loops. Each of the erase loops may include an erase voltage applying operation and an erase verify operation. During an erase voltage applying operation, the erase operation controller 161 may control the voltage generator 120 and the address decoder 130 to apply an erase permission voltage (e.g., a ground voltage) to a word line coupled to a selected memory block. The erase operation controller 161 may control the voltage generator 120 and the page buffer group 140 to apply an erase voltage to a bit line and/or a common source line coupled to the selected memory block.

During an erase verify operation, the erase operation controller 161 may determine whether threshold voltages of the memory cells included in the selected memory block are less than an erase verify voltage. More specifically, the erase operation controller 161 may apply an erase verify voltage to word lines of the selected memory block and determine whether threshold voltages of the memory cells are less than the erase verify voltage through bit lines. The erase operation controller 161 may determine that the erase verify operation passes when the number of bit lines including a memory cell having a threshold voltage greater than the erase verify voltage, i.e., when a fail bit count is less than or equal to a predetermined reference count. On the other hand, the erase operation controller 161 may determine that the erase verify operation fails when the number of bit lines including a memory cell having a threshold voltage greater than the erase verify voltage exceeds the predetermined reference count.

The erase operation controller 161 may terminate the erase operation when the erase verify operation passes. On the other hand, the erase operation controller 161 may perform a next erase loop when the erase verify operation fails. The erase operation controller 161 may increase a magnitude of an erase voltage, which is applied during an erase voltage applying operation, by a step voltage each time the erase loop increases. This is called an incremental step pulse erase (ISPE) scheme.

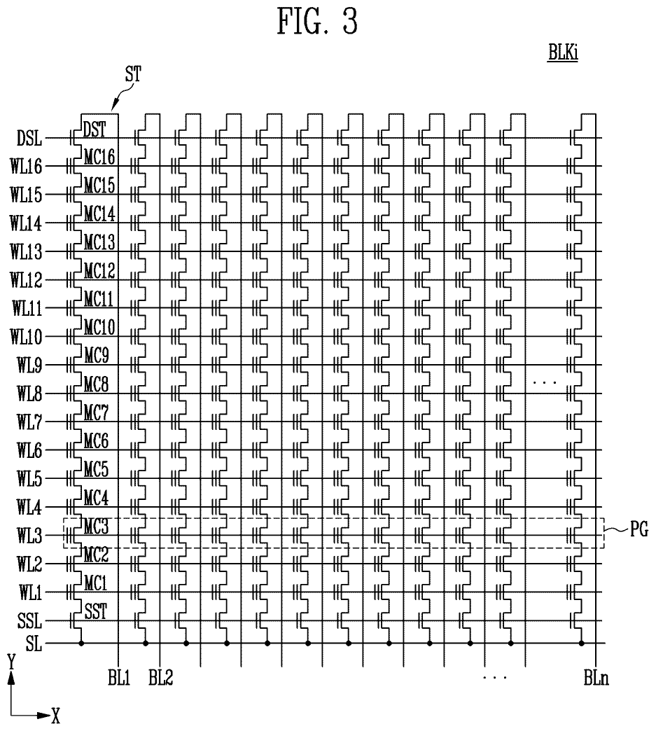

FIG. 3 is a diagram illustrating a detailed configuration of a memory block BLKi shown in FIG. 2, according to an embodiment of the present disclosure.

The memory block BLKi as shown in FIG. 3 is one of the memory blocks BLK1 to BLKz as shown in FIG. 2.

The memory block BLKi may include a plurality of memory cells which are coupled to a plurality of word lines, respectively, arranged in parallel between a first select line and a second select line. The first select line may be a source select line SSL, and the second select line may be a drain select line DSL. More specifically, the memory block BLKi may include a plurality of cell strings ST that are coupled between the bit lines BL1 to BLn and a source line SL. The bit lines BL1 to BLn may be coupled to the cell strings ST, respectively, and the source line SL may be commonly coupled to the cell strings ST. The cell strings ST may have the same configuration. Thus, the cell string ST which is coupled to the first bit line BL1 among the cell strings ST is described below in detail as an example.

The cell string ST may include a source select transistor SST, a plurality of memory cells MC1 to MC16, and a drain select transistor DST which are coupled in series to each other between the source line SL and the first bit line BL1. Each cell string ST may include at least one source select transistor SST, at least one drain select transistor DST, and more memory cells than the memory cells MC1 to MC16 as shown in FIG. 3.

A source of the source select transistor SST may be coupled to the source line SL or the common source line, and a drain of the drain select transistor DST may be coupled to the first bit line BL1. The memory cells MC1 to MC16 may be coupled in series between the source select transistor SST and the drain select transistor DST. Gates of the source select transistors SST included in different cell strings ST may be coupled to the source select line SSL, gates of the drain select transistors DST may be coupled to the drain select line DSL, and gates of the memory cells MC1 to MC16 may be coupled to a plurality of word lines WL1 to WL16, respectively. A group of memory cells coupled to the same word line, among memory cells included in different cell strings ST, may constitute one physical page PG. Therefore, the memory block BLKi may include as many physical pages PG as the number of word lines WL1 to WL16.

Various tests may be performed during manufacturing processes of the memory device 100. During a test, a bad column line (a bad bit line) may be detected among a plurality of column lines which constitute the memory cell array 110. Since the column lines of the memory cell array 110 are bit lines, a bad column line may be a bad bit line. Memory cells which are coupled to the bad column line among the bit lines constituting the memory block BLKi cannot operate properly. Thus, the bad column line needs to be replaced by a normal column line. That is, during the manufacturing processes of the memory device 100, the bad column line may be replaced by a preliminary column line called a redundancy column line.

However, the bad column line may affect an erase operation since the erase operation is performed in a unit of a single memory block which is physically connected thereto. The memory device 100 may control a page buffer which is coupled to the bad column line so that the bad column line may not be involved in the erase operation.

More specifically, the memory device 100 may perform a masking operation to forcibly store a predetermined value in a latch included in the page buffer coupled to the bad column line during the erase operation. The memory device 100 may store the predetermined value in the page buffer coupled to bad column lines such that the bad column lines may not be engaged in an erase verify operation, regardless of whether the data is erased.

However, when data transfer between latches in the page buffer fails, the masking operation may not be performed properly, which may cause bad column lines to be involved in the erase operation. As a result, the erase operation may not be performed normally.

According to an embodiment, a memory device may prevent an error in an erase operation caused by a masking fail column (i.e., masking fail bit line) by detecting the masking fail column in which an error occurs in a masking operation, and reflecting the number of detected masking fail columns into a fail bit count used during the erase operation.

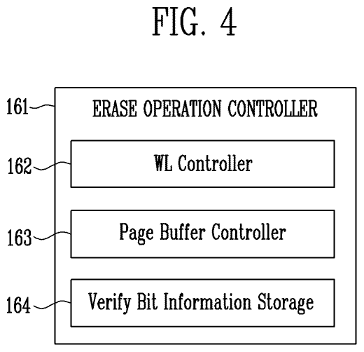

FIG. 4 is a diagram illustrating a detailed configuration of the erase operation controller 161 shown in FIG. 2, according to an embodiment of the present disclosure.

Referring to FIGS. 2 to 4, the erase operation controller 161 may include a word line controller 162, a page buffer controller 163, and a verify bit information storage 164.

The word line controller 162 may provide control signals for controlling a peripheral circuit to apply an erase permission voltage to a word line during an erase operation. More specifically, the word line controller 162 may provide control signals to a peripheral circuit such that the erase permission voltage may be provided to word lines coupled to a selected memory block during an erase voltage applying operation included in an erase loop. In addition, the word line controller 162 may provide control signals to the peripheral circuit to apply the erase verify voltage to the word lines coupled to the selected memory block during the erase verify operation.

The page buffer controller 163 may control a bit line during an erase operation. For example, the page buffer controller 163 may provide control signals to the peripheral circuit to apply an erase voltage to a bit line during an erase voltage applying operation included in an erase loop. The page buffer controller 163 may provide control signals to peripheral circuit to detect whether threshold voltages of memory cells have a magnitude greater than or equal to an erase verify voltage through bit lines during an erase verify operation.

The page buffer controller 163 may control a masking operation. More specifically, the page buffer controller 163 may control page buffers to perform a masking operation on bad column lines during the erase verify operation.

The verify bit information storage 164 may store information on a predetermined reference count used during an erase verify operation. The information about the predetermined reference count used during the erase verify operation may include information about the number of masking fail columns corresponding to column lines which are not masked among bad column lines. According to an embodiment, the information about the predetermined reference count may refer to a value obtained by adding the number of masking fail columns corresponding to columns, which are not masked among the bad columns, to a reference value which is determined through different tests.

The information about the predetermined reference count may be stored in a content addressable memory (CAM) block among the memory blocks BLK1 to BLKz included in the memory cell array 110. When power is applied to the memory device 100, the control logic 160 may read the information about the predetermined reference number stored in the CAM block and store the information in the verify bit information storage 164. The verify bit information storage 164 may provide the information about the predetermined reference count to the page buffer group 140 during the erase verify operation.

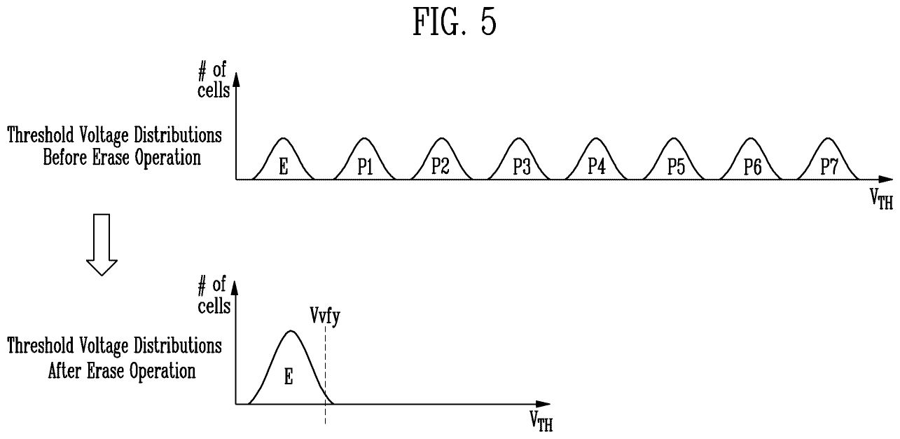

FIG. 5 is a diagram illustrating a threshold voltage distribution of memory cells during an erase operation, according to an embodiment of the present disclosure.

In FIG. 5, a single memory cell stores data in a TLC method of storing 3-bit data. Since one memory cell stores three bits of data, memory cells may have (2³=8) threshold voltages corresponding to one of a total of eight states including an erase state E and first to seventh program states P1 to P7 before an erase operation is performed.

The erase operation may refer to an operation of reducing the threshold voltages of the memory cells such that the threshold voltages of the memory cells may be included in a threshold voltage distribution corresponding to the erase state E. Therefore, when the erase operation is completed, the memory cells may have the threshold voltages corresponding to the erase state E. A voltage which is used during an erase verify operation of determining whether the threshold voltages of the memory cells correspond to the erase state may be an erase verify voltage Vvfy.

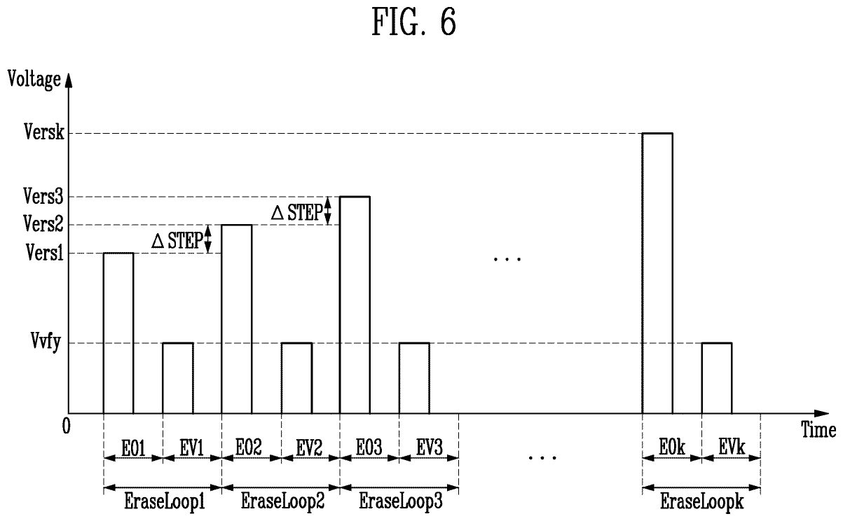

FIG. 6 is a diagram illustrating an erase operation, according to an embodiment of the present disclosure.

Referring to FIG. 6, the erase operation may include a plurality of erase loops EraseLoop1 to EraseLoopk, where k is a natural number of 2 or more. Each of the erase loops EraseLoop1 to EraseLoopk may include a corresponding one of a plurality of erase voltage applying operations EO1 to EOk and a corresponding one of erase verify operations EV1 to EV4. The plurality of erase loops EraseLoop1 to EraseLoopk may be sequentially performed. During each erase loop, one of the erase voltage applying operations EO1, EO2, EO3, . . . , and EOK using erase voltages Vers1 to Versk and one of the erase voltage verify operations EV1, EV2, EV3, . . . , and EVk using the erase verify voltage Vvfy may be performed.

The first erase loop EraseLoop1 may include the first erase voltage applying operation EO1 and the first erase verify operation EV1.

During the first erase voltage applying operation EO1, the memory device may apply the first erase voltage Vers1 to the common source line (or the source line) and/or the bit line as described above with reference to FIG. 3, and may apply an erase permission voltage (e.g., a ground voltage) to all of the plurality of word lines of the selected memory block.

During the first erase verify operation EV1, the memory device may apply the erase verify voltage Vvfy to the word lines as described above with reference to FIG. 3, and may determine threshold voltages of the memory cells through the bit lines.

More specifically, memory cells having threshold voltages which are less than or equal to the erase verify voltage Vvfy may be turned on by the erase verify voltage Vvfy applied to a word line. Memory cells having threshold voltages greater than the erase verify voltage Vvfy may not be turned on (i.e., may be turned off) even when the erase verify voltage Vvfy is applied to the word line. Therefore, a bit line coupled to a cell string which includes at least one memory cell having a greater threshold voltage than the erase verify voltage Vvfy and a bit line coupled to a cell string which includes only memory cells having threshold voltages which are less than or equal to the erase verify voltage Vvfy may include different voltages or current values. By the above-described principle, the memory device may count fail bits corresponding to the number of bit lines including at least one memory cell having a greater threshold voltage than the erase verify voltage Vvfy. The memory device may compare a fail bit count with a predetermined reference count. When the fail bit count is the predetermined reference count or less, the memory device may determine that the first erase verify operation EV1 passes. On the other hand, when the fail bit count exceeds the predetermined reference count, the memory device may determine that the first erase verify operation EV1 fails.

When the first erase verify operation passes, the erase operation may end. When the first erase verify operation fails, the second erase loop EraseLoop2 may be performed.

The second erase loop EraseLoop2 may include the second erase voltage applying operation EO2 and the second erase verify operation EV2.

During the second erase voltage applying operation EO2, the memory device may apply the second erase voltage Vers2 to the common source line (or the source line) and/or the bit line, and may apply an erase permission voltage (e.g., a ground voltage) to all of the plurality of word lines of the selected memory block. The second erase voltage Vers2 may be greater than the first erase voltage Vers1 by a step voltage STEP. The memory device may increase the erase voltage by the step voltage STEP from the previous erase loop. This is called an incremental step pulse erase (ISPE) scheme.

After the second erase voltage applying operation EO2 is performed, the second erase verify operation EV2 may be performed. The second erase verify operation EV2 may be performed in the same manner as in the first erase verify operation EV1.

As illustrated in FIG. 5, only the levels of the erase voltages Vers1 to Versk are increased as the erase loop is performed. However, the embodiments of the present disclosure are not limited thereto. For example, the level of the erase verify voltage Vvfy may also be increased.

In addition, in various embodiments, as an erase loop is repeated, the levels of the erase voltages Vers1 to Versk or the level of the erase verify voltage Vvfy may be reduced.

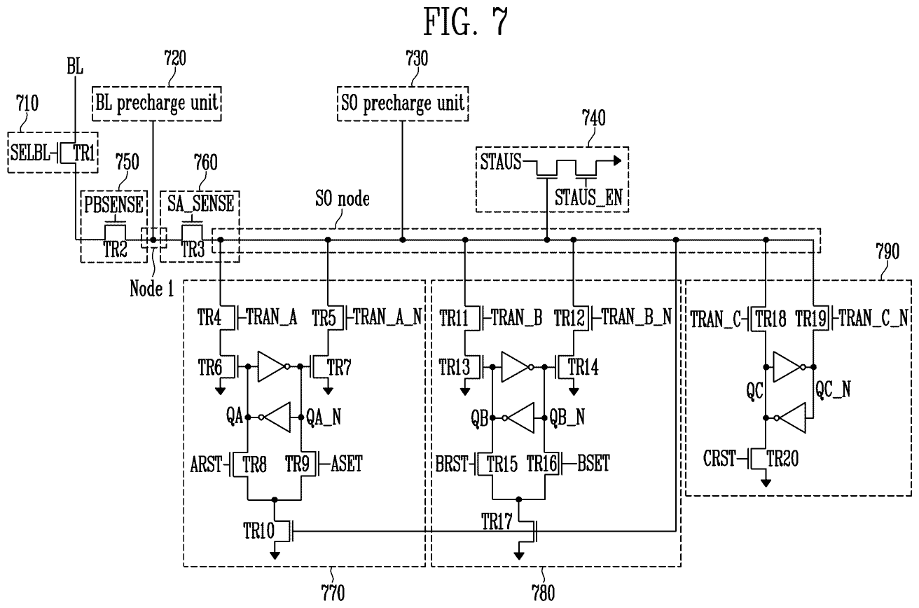

FIG. 7 is a diagram illustrating a detailed configuration of one page buffer PB among the page buffers PB1 to PBn included in the page buffer group 140 shown in FIG. 2, according to an embodiment of the present disclosure.

Referring to FIG. 7, the page buffer PB may include a bit line selecting unit 710, a bit line precharge unit 720, a sensing node (SO) precharge unit 730, a status output unit 740, a first sensing unit 750, a second sensing unit 760, a sensing latch 770, a transfer latch 780, and an input/output latch 790.

The bit line selecting unit 710 may select a bit line BL. The bit line selecting unit 710 may include a first transistor TR1 which is turned on in response to a bit line select signal SELBL. Based on the bit line select signal SELBL, the bit line BL may be coupled to or released from the first sensing unit 750.

The bit line precharge unit 720 may provide a precharge voltage to the bit line BL. The bit line precharge unit 720 may receive a voltage generated by the voltage generator 120 as described above with reference to in FIG. 2 and provide the received voltage.

The sensing node precharge unit 730 may provide a precharge voltage to a sensing node SO node.

The status output unit 740 may output a status signal STATUS which indicates a status of the sensing node SO node, based on a status enable signal STATUS_EN.

The first sensing unit 750 may include a second transistor TR2 which is turned on in response to a page buffer sensing signal PBSENSE. The second transistor TR2 may be coupled in series with the first transistor TR1 of the bit line selecting unit 710. When the bit line precharge unit 720 provides the precharge voltage to a first node Node 1 and the page buffer sensing signal PBSENSE is provided to the first sensing unit 750, the precharge voltage may be provided to the bit line.

The second sensing unit 760 may include a third transistor TR3 which is turned on in response to a sensing control signal SA_SENSE. The third transistor TR3 may be coupled in series with the second transistor TR2 of the first sensing unit 750. The bit line precharge unit 720 may be coupled between the first sensing unit 750 and the second sensing unit 760. For example, the bit line precharge unit 720 may be coupled between a drain-side terminal of the second transistor TR2 and a source-side terminal of the third transistor TR3.

The sensing latch 770, the transfer latch 780, the input/output latch 790, and the sensing node precharge unit 730 may be commonly coupled to the sensing node SO node. That is, the sensing latch 770, the transfer latch 780, the input/output latch 790, and the sensing node precharge unit 730 may be coupled in parallel with each other.

The sensing latch 770 may include a latch which stores a result of sensing a voltage or current in a bit line. The sensing latch 770 may include an A latch connected between the inverted QA node QA_N and the QA node QA, a fourth transistor TR4 turned on by the latch A transfer control signal TRAN_A connected between the sensing node SO_node and the QA node QA, and a sixth transistor TR6 turned on by the voltage of the QA node QA. In addition, the sensing latch 770 may include a fifth transistor TR5 turned on by the latch A transfer inverting control signal TRAN_A_N connected between the sensing node SO_node and the inverted QA node QA_N, and a sixth transistor TR6 turned on by the voltage of the inverted QA node QA_N. Furthermore, the sensing latch 770 may include an eighth transistor TR8 turned on by the A latch reset signal ARST connected between the QA node QA and the ground, and a ninth transistor turned on by the A latch set control signal ASET connected between the inverted QA node QA_N and the ground.

The transfer latch 780 may receive a value which is stored in the latch included in the sensing latch 770 or a value which is stored in a latch included in the input/output latch 790. The transfer latch 780 may include a B latch connected between the inverted QB node QB_N and the QB node QB, an eleventh transistor TR11 turned on by the latch B transfer control signal TRAN_B connected between the sensing node SO_node and the QB node QB, and a thirteenth transistor TR13 turned on by the voltage of the QB node QB. In addition, the transfer latch 780 may include a twelfth transistor TR12 turned on by the latch B transfer inverting control signal TRAN_B_N connected between the sensing node SO_node and the inverted QB node QB_N, and a fourteenth transistor TR14 turned on by the voltage of the inverted QB node QB_N. Furthermore, the transfer latch 780 may include a fifteenth transistor TR15 turned on by the B latch reset signal BRST connected between the QB node QB and the ground, and a sixteenth transistor turned on by the B latch set control signal BSET connected between the inverted QB node QB_N and the ground.

The input/output latch 790 may include the latch which receives a value outside from the page buffer PB. The input/output latch 790 may output the value stored in the latch to the outside of the page buffer PB. The input/output latch 790 may include a C latch connected between the inverted QC node QC_N and the QC node QC, and an eighteenth transistor TR18 turned on by the C latch transfer control signal TRAN_C connected between the sensing node SO_node and the QC node QC. In addition, the input/output latch 790 may include a nineteenth transistor TR19 turned on by the latch C transfer inverting control signal TRAN_C_N connected between the sensing node SO_node and the inverted QC node QC_N. Furthermore, the input/output latch 790 may include a twentieth transistor TR20 turned on by the C latch reset signal CRST connected between the QC node QC and the ground.

According to an embodiment, the sensing latch 770, the transfer latch 780, and the input/output latch 790 may be referred to as a latch A, a latch B, and a latch C, respectively. Generally, during a program operation, a read operation, and an erase operation of a memory device, the latch A, the latch B, and the latch C may store a value of a voltage or current detected through the bit line BL, or may receive and maintain a value from another latch.

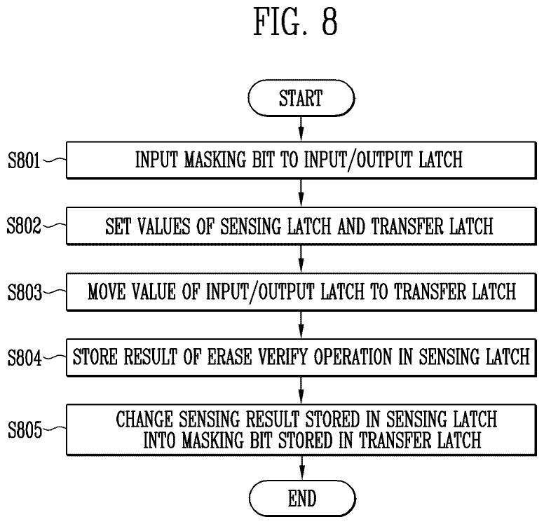

FIG. 8 is a flowchart for describing a masking operation of a bad column, according to an embodiment of the present disclosure.

In general, a memory device may detect a bad column through a test at a wafer stage. Information about the detected bad column may be stored in a CAM block.

The bad column may not affect an erase operation by a masking operation which allows the bad column to be treated as an erase verify pass during an erase verify operation. Therefore, a predetermined value may be stored in a latch of a page buffer coupled to the bad column during the verify erase operation such that the bad column may be treated as an erase verify pass by a masking operation. During the masking operation, data transfer PB TRANSFER between the latches included in the page buffer PB may be performed.

According to an embodiment, the page buffer controller 163 as described above with reference to FIG. 4 may control the page buffer PB to perform the masking operation during the erase verify operation.

A method of operating a masking operation will be described below with reference to FIGS. 6 to 8.

At operation S801, a masking bit may be input to the input/output latch 790.

More specifically, a voltage (value) corresponding to the masking bit may be applied to an inverting QC node QC_N of the input/output latch 790 of the page buffer PB. A value of the inverting QC node QC_N may be determined depending on whether the bit line BL coupled to the page buffer PB is a bad column or a normal column. Values which are input to the inverting QC node QC_N are as shown below in [Table 1].

TABLE 1

| | BAD COLUMN | NORMAL COLUMN |
|---|---|---|
| QC_N | 1′b(VCORE) | 0′b(GND) |

When the bit line BL coupled to the page buffer PB is a bad column, a value of 1′b(VCORE) is input to the inverting QC node QC_N. On the other hand, when the bit line BL is a normal column, a value of 0′b(GND) is input to the inverting QC node QC_N. In the above table, “1” refers to logic high and a core voltage VCORE is applied. In addition, “0” refers to logic low and a ground voltage GND is applied.

At operation S802, the values of the sensing latch 770 and the transfer latch 780 may be set.

More specifically, the sensing node precharge unit 730 may apply a precharge voltage to the sensing node SO node (SO node: 1′b(VCORE)). As the sensing node SO node is precharged, a 10th transistor TR10 and a 17th transistor TR17 may be turned on.

Subsequently, a latch A setting control signal ASET and a latch B setting control signal BSET may be applied to a ninth transistor TR9 of the sensing latch 770 and a 16th transistor TR16 of the transfer latch 780. As a result, the ninth transistor TR9 and the 16th transistor TR16 may be turned on. As the ninth transistor TR9, the 10th transistor TR10, the 16th transistor TR16, and the 17th transistor TR17 are turned on, an inverting QA node QA_N and an inverting QB node QB_N may be discharged to the ground voltage GND. Thus, a value of both the inverting QA node QA_N and the inverting QB node QB_N may be 0′b(GND).

At operation S803, a value of the input/output latch 790 may be moved to the transfer latch 780.

More specifically, when the sensing node precharge unit 730 charges the sensing node SO node with the precharge voltage (SO node: 1′b(VCORE)), a latch C transfer inverting control signal TRAN_C_N may be applied to a gate of a 19th transistor TR19. As a result, the 19th transistor TR19 may be turned on. A value of the sensing node SO node may vary depending on the value stored in the inverting QC node QC_N. For example, when the bit line BL is a normal column, a value of 0′b(GND) may be input to the inverting QC node QC_N, and a voltage of the sensing node SO node may be discharged in line with the 19th transistor TR19. Thus, the sensing node SO node may also have the value of 0′b(GND). On the other hand, when the bit line BL is a bad column, a value of 1′b(VCORE) may be input to the inverting QC node QC_N, and the value of the sensing node SO node may be maintained. As a result, the value of the sensing node SO node may be set to be the same value as that of the inverting QC node QC_N.

When a latch B reset signal BRST which is applied to a gate of a 15th transistor TR15 is enabled, the 15th transistor TR15 may be turned on.

When the bit line BL is a bad column, the sensing node SO node may have the same value as 1′b(VCORE) which is the value of the inverting QC node QC_N, so that the 17th transistor TR17 may be turned on. Therefore, a value of a QB node QB may be discharged in line with the 15th transistor TR15 and the 17th transistor TR17. The value of 0′b(GND) of the inverting QB node QB_N which is set at the operation S802 may be changed to 1′b(VCORE) which is the same value as that of the inverting QC node QC_N. Alternatively, when the bit line BL is a normal column, the sensing node SO node may have the same value as 0′b(GND) which is the value of the inverting QC node QC_N. As a result, the 17th transistor TR17 may not be turned on. Accordingly, the value of the QB node QB may not be discharged. Thus, the value of the inverting QB node QB_N which is set at the operation S802 may be maintained at 0′b(GND) which is the same value as the inverting QC node QC_N.

At operation S804, a result of the erase verify operation may be stored in the sensing latch 770.

During the erase verify operation as described above with reference to FIG. 6, when the bit line BL is a normal column, the value of 1′b(VCORE) may be stored as a result of sensing a bit line coupled to a cell string including only memory cells having threshold voltages less than or equal to the erase verify voltage Vvfy in the inverting QA node QA_N. On the other hand, when the bit line BL is a bad column, the value of 0′b(GND) may be stored in the inverting QA node QA_N. Therefore, to prevent the erase operation from being affected by the bad column, a masking operation may be performed to change the value of 0′b(GND) stored in the inverting QA node QA_N into the value of 1′b(VCORE) which is the same value as in the normal column.

At operation S805, the sensing result stored in the sensing latch 770 may be changed into a masking bit stored in the transfer latch 780.

The method of moving the value of the transfer latch 780 to the sensing latch 770 is similar to the process by which the value of the input/output latch 790 is moved to the transfer latch 780.

More specifically, when the sensing node precharge unit 730 charges the sensing node SO node with the precharge voltage (SO node: 1′b(VCORE)), a latch B transfer inverting control signal TRAN_B_N may be applied to a gate of a 12th transistor TR12. As a result, the 12th transistor TR12 may be turned on. The value of the sensing node SO node may then be set to the same value as that stored in the inverting QB node QB_N.

Subsequently, when a latch A reset signal ARST which is applied to a gate of an eighth transistor TR8 is enabled, the eighth transistor TR8 may be turned on. In a bad column, a value of the sensing node SO node may be 1′b(VCORE). Thus, the value of the inverting QA node QA_N which is stored at the operation S804 may change from 0′b(GND) to 1′b(VCORE). However, in a normal column, the value of the sensing node SO node may be 0′b(GND). Thus, even when the latch A reset signal ARST is enabled, the value of the inverting QA node QA_N stored at the operation S804 may not be changed.

The values of the inverting QA node QA_N at steps S804 and S805 as described above are shown as below in [TABLE 2].

TABLE 2

| | BAD COLUMN | NORMAL COLUMN | TIME |
|---|---|---|---|
| QA_N | 0′b(GND) | 1′b(VCORE) | After sensing |
| | 1′b(VCORE) | 1′b(VCORE) | After masking |

The masking operation performed through operations S801 to S805 may be performed by inputting a masking bit to store (change) to the input/output latch 790 included in the page buffer PB, and performing the data transfer PB TRANSFER of transferring the input masking bit from the input/output latch 790 to the transfer latch 780 and then from the transfer latch 780 to the sensing latch 770. By inputting 1′b(VCORE) corresponding to the masking bit to the inverting QC node QC_N, transferring the masking bit to the inverting QB node QB_N, and transferring the masking bit back to the inverting QA node QA_N, the bad column may be controlled to operate as a normal column.

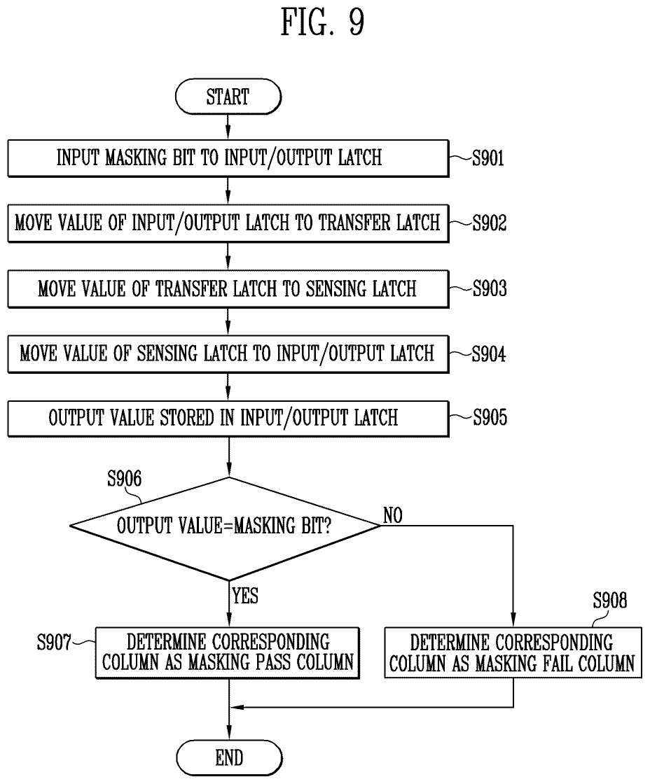

FIG. 9 is a flowchart for describing a method of detecting a masking fail column, according to an embodiment of the present disclosure.

According to an embodiment, the page buffer controller 163 as described above with reference to FIG. 4 may control the page buffer PB to perform an operation of detecting a masking fail column.

Referring to FIGS. 6, 7, and 8, at operation S901, a masking bit may be input to the input/output latch 790. That is, 1′b(VCORE) corresponding to the masking bit of the bad column may be input to the inverting QC node QC_N.

At operation S902, a value stored in the input/output latch 790 may be transferred to the transfer latch 780.

More specifically, when the sensing node precharge unit 730 charges the sensing node SO node with the precharge voltage (SO node: 1′b(VCORE)), the latch C transfer inverting control signal TRAN_C_N may be applied to a gate of the 19th transistor TR19. As a result, the 19th transistor TR19 may be turned on. A value of the sensing node SO node may vary depending on the value stored in the inverting QC node QC_N. For example, since 1′b(VCORE) is input to the inverting QC node QC_N, the value of the sensing node SO node may be maintained at 1′b(VCORE) which is the same value as that of the inverting QC node QC_N.

Subsequently, when the latch B reset signal BRST which is applied to the gate of the 15th transistor TR15 is enabled, the 15th transistor TR15 may be turned on. The sensing node SO node may have the same value as 1′b(VCORE) corresponding to the value of the inverting QC node QC_N, so that the 17th transistor TR17 may be turned on. Therefore, a value of the QB node QB may be discharged in line with the 15th transistor TR15 and the 17th transistor TR17. As a result, the value of the inverting QB node QB_N may change from 0′b(GND) to 1′b(VCORE) which is the same value as that of the inverting QC node QC_N.

At operation S903, the value stored in the transfer latch 780 may be transferred to the sensing latch 770.

More specifically, when the sensing node precharge unit 730 charges the sensing node SO node with the precharge voltage (SO node: 1′b(VCORE)), the latch B transfer inverting control signal TRAN_B_N may be applied to a gate of the 12th transistor TR12. As a result, the 12th transistor TR12 may be turned on. The value of the sensing node SO node may then be set to the same value stored in the inverting QB node QB_N.

Subsequently, when the latch A reset signal ARST which is applied to a gate of the eighth transistor TR8 is enabled, the eighth transistor TR8 may be turned on. Since the value of the sensing node SO node is 1′b(VCORE), the value of the inverting QA node QA_N may be changed to 1′b(VCORE).

At operation S904, the value stored in the sensing latch 770 may be transferred back to the input/output latch 790.

More specifically, when the sensing node precharge unit 730 charges the sensing node SO node with a precharge voltage (SO node: 1′b(VCORE), a latch A transfer inverting control signal TRAN_A_N may be applied to a gate of a fifth transistor TR5. As a result, the fifth transistor TR5 may be turned on. The value of the sensing node SO node may then be set to the same value as that stored in the inverting QA node QA_N.

Subsequently, the latch C transfer inverting control signal TRAN_C_N may be applied to the gate of the 19th transistor TR19. As a result, the 19th transistor TR19 may be turned on. The value of the sensing node SO node may be transferred to the inverting QC node QC_N.

At operation S905, the value stored in the input/output latch 790 may be output.

At operation S906, it may be determined whether the value which is output from the input/output latch 790 coincides with the masking bit which is input at the operation S901. As a result of determination, when the value which is output from the input/output latch 790 coincides with the masking bit (i.e., “YES” in the operation S906), there are no errors in the data transfer PB TRANSFER. The process flow proceeds to operation S907, and the corresponding column is determined as a masking pass column. When the value which is output from the input/output latch 790 does not coincide with the masking bit (i.e., “NO” in the operation S906), there exist errors in the data transfer PB TRANSFER where the masking bit which is input to the input/output latch 790 is transferred to the transfer latch 780 and the sensing latch 770 and back to the input/output latch 790. Thus, the process flow proceeds to operation S908, and the corresponding column is determined as a masking fail column.

When there are no errors in the data transfer PB TRANSFER operation, a value of each node is as shown below in [TABLE 3].

TABLE 3

| | Value of each node (1-VCORE, 0-GND) | | | |
|---|---|---|---|---|
| Operation | SO | QC_N | QB_N | QA_N |
| Data input | | 1/0 | | |
| SO precharge | 1 | | | |
| BSET | | | 0 | |
| ASET | | | | 0 |
| TRANC_N | 1/0 | | | |
| BRST | | | 1/0 | |
| SO precharge | 1 | | | |
| TRAN_B_N | 1/0 | | | |
| ARST | | | | 1/0 |
| SO precharge | 1 | | | |
| TRAN_A_N | 1/0 | | | |
| TRANC_N(CON1) | | 1/0 | | |

When errors occur in the data transfer PB TRANSFER operation, a value of each node is as shown below in [TABLE 4].

TABLE 4

| | Value of each node (1-VCORE, 0-GND) | | | |
|---|---|---|---|---|
| Input controls signal | SO | QC_N | QB_N | QA_N |
| Data input | | 1/0 | | |
| SO precharge | 1 | | | |
| BSET | | | 0 | |
| ASET | | | | 0 |
| TRANC_N | 1/0 | | | |
| BRST | | | 0/0 | |
| SO precharge | 1 | | | |
| TRAN_B_N | 0/0 | | | |
| ARST | | | | 1/0 |
| SO precharge | 1 | | | |
| TRAN_A_N | 0/0 | | | |
| TRANC_N(CON1) | | 0/0 | | |

At the operation S907, the memory device may update information about a verify bit which is used during an erase verify operation. More specifically, the memory device may set a predetermined reference count for the erase verify operation to a sum of a reference value determined through various tests during the manufacturing processes of the memory device 100 and the number of masking fail columns.

According to an embodiment of the present disclosure, a memory device may perform a masking operation on a bad column during manufacturing and testing processes of the memory device, detect masking fail columns, and reflect a masking fail column count into a predetermined reference count to be compared with a fail bit count during an erase verify operation to perform an erase operation without errors even when the masking operation of the bad column fails.

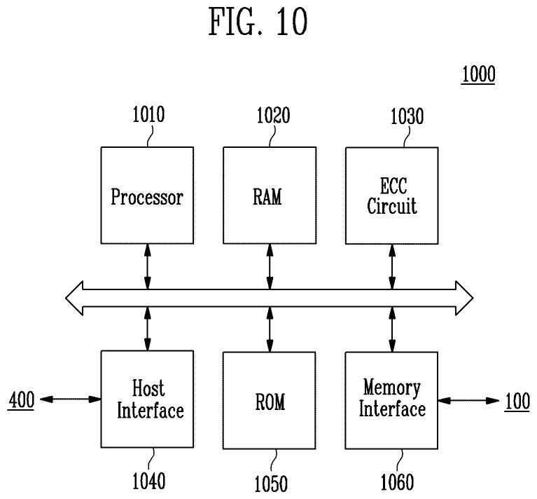

FIG. 10 is a diagram illustrating a detailed configuration of the controller 200 shown in FIG. 1, according to an embodiment of the present disclosure.

Referring to FIG. 10, a memory controller 1000 may include a processor 1010, a RAM 1020, an ECC circuit 1030, a host interface 1040, a ROM 1050, and a memory interface 1060. The memory controller 1000 may correspond to the controller 200 as described above with reference to FIG. 1.

The processor 1010 may control the general operations of the memory controller 1000. The RAM 1020 may serve as a buffer memory, a cache memory, or a working memory of the memory controller 1000.

In an embodiment, the ROM 1050 may store various types of information, required for the memory controller 1000 to operate, in the form of firmware.

The memory controller 1000 may communicate with an external device, for example, the host 400 and an application processor, through the host interface 1040.

The memory controller 1000 may communicate with the memory device 100 through the memory interface 1060. The memory controller 1000 may transfer a command CMD, the address ADDR and a control signal CTRL to the memory device 100 or may receive data DATA through the memory interface 1060.

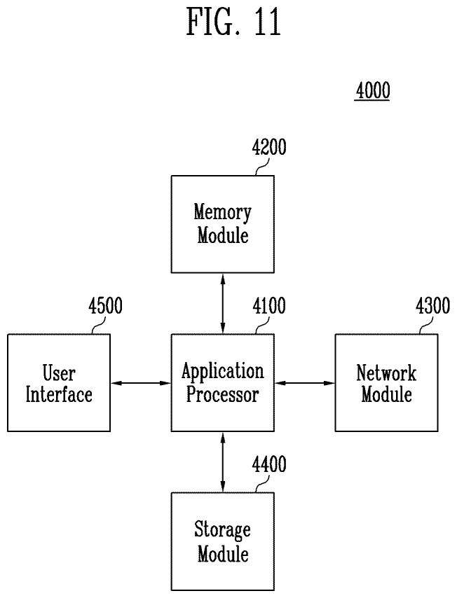

FIG. 11 is a block diagram illustrating a user system 4000 a configuration of a data storage device, according to an embodiment of the present disclosure.

Referring to FIG. 11, the user system 4000 may include an application processor 4100, a memory module 4200, a network module 4300, a storage module 4400, and a user interface 4500.

The application processor 4100 may run components included in the user system 4000, an Operating System (OS), or a user program. In an embodiment, the application processor 4100 may include controllers, interfaces, graphic engines, etc. for controlling the components included in the user system 4000. The application processor 4100 may be provided as a system-on-chip (SoC).

The memory module 4200 may function as a main memory, a working memory, a buffer memory or a cache memory of the user system 4000. The memory module 4200 may include volatile RAMs such as DRAM, SDRAM, DDR SDRAM, DDR2 SDRAM, DDR3 SDRAM, LPDDR SDARM, LPDDR2 SDRAM, and LPDDR3 SDRAM or nonvolatile RAMs such as PRAM, ReRAM, MRAM, and FRAM. In an embodiment, the application processor 4100 and the memory module 4200 may be packaged based on package-on-package (POP) and provided as a single semiconductor package.

The network module 4300 may communicate with external devices. For example, the network module 4300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), WiMAX, WLAN, UWB, Bluetooth®, or Wi-Fi communication. In an embodiment, the network module 4300 may be included in the application processor 4100.

The storage module 4400 may store data. For example, the storage module 4400 may store data received from the application processor 4100. Alternatively, the storage module 4400 may transfer the data stored in the storage module 4400 to the application processor 4100. In an embodiment, the storage module 4400 may be implemented as a nonvolatile semiconductor memory device, such as a Phase-change RAM (PRAM), a Magnetic RAM (MRAM), a Resistive RAM (RRAM), a NAND flash memory, a NOR flash memory, or a NAND flash memory having a three-dimensional (3D) structure. In an embodiment, the storage module 4400 may be the data storage device 50 as described above with reference to FIG. 1. According to various embodiments, the storage module 4400 may be provided as a removable storage medium (i.e., a removable drive), such as a memory card or an external drive of the user system 4000.

For example, the storage module 4400 may include a plurality of non-volatile memory devices, and the plurality of non-volatile memory devices may operate in the same manner as the memory device 100 described above with reference to FIG. 1. The storage module 4400 may operate in the same manner as the storage device 50 as described above with reference to FIG. 1.

The user interface 4500 may include interfaces which input data or commands to the application processor 4100 or output data to an external device. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric device. The user interface 4500 may further include user output interfaces such as a Liquid Crystal Display (LCD), an Organic Light Emitting Diode (OLED) display device, an Active Matrix OLED (AMOLED) display device, an LED, a speaker, and a monitor.

According to the embodiments of the present disclosure, a memory device performing an erase operation and a method of operating the memory device may be provided. Furthermore, the embodiments may be combined to form additional embodiments.

What is claimed is:

1. A memory device comprising:
a memory block including memory cells arranged corresponding to bit lines and word lines;
a peripheral circuit configured to perform an erase operation of erasing data stored in the memory cells; and
an erase operation controller configured to apply an erase verify voltage to the word lines during the erase operation, and determine whether the erase operation is completed based on a result of comparing a predetermined reference count with a fail bit count, the fail bit count corresponding to a number of bit lines coupled to one or more memory cells having threshold voltages greater than the erase verify voltage,
wherein the predetermined reference count is a sum of a predetermined reference value and a number of masking fail columns in which a masking operation fails, among the bit lines.

2. The memory device of claim 1, wherein the peripheral circuit includes page buffers coupled to the bit lines, respectively.

3. The memory device of claim 2, wherein the erase operation includes one or more erase loops, each erase loop including an erase voltage applying operation of applying an erase voltage to the word lines and an erase verify operation of comparing the fail bit count with the predetermined reference count.

4. The memory device of claim 3, wherein the erase operation controller includes a page buffer controller, during the erase verify operation, configured to control the page buffers to perform the masking operation on a page buffer coupled to a bit line corresponding to a bad column, among the bit lines.

5. The memory device of claim 4, wherein each of the page buffers includes a first latch, a second latch, and a third latch coupled in parallel with each other.

6. The memory device of claim 5, wherein the page buffer controller is configured to:
input a masking bit to the first latch;
move the masking bit input to the first latch to the second latch;
store a result of comparing the erase voltage with a threshold voltage of a corresponding memory cell in the third latch; and
store the masking bit moved to the second latch in the third latch.

7. The memory device of claim 1, wherein the predetermined reference count is a value determined through a test of the memory device.

8. The memory device of claim 6, wherein one of the masking fail columns is a bit line coupled to a page buffer failing in moving the masking bit input to the first latch, to the second latch during the masking operation.

9. The memory device of claim 6, wherein one of the masking fail columns is a bit line coupled to a page buffer failing in storing the masking bit, moved to the second latch, in the third latch during the masking operation.

10. The memory device of claim 3, wherein the erase operation controller is configured to increase the erase voltage by a step voltage each time an erase loop iterates.

11. A memory device comprising:
a cell string including memory cells coupled in series and coupled to word lines, respectively;
a page buffer including latches coupled to the cell string through a bit line; and
a page buffer controller configured to control the page buffer to input a masking bit to an input/output latch among the latches and perform a data transfer operation by moving the masking bit to other latches except the input/output latch, among the latches.

12. The memory device of claim 11, wherein the page buffer controller is configured to move the masking bit input to the input/output latch, to a transfer latch coupled in parallel with the input/output latch, among the latches.

13. The memory device of claim 12, wherein the page buffer controller is configured to move a value moved to the transfer latch, to a sensing latch coupled in parallel with the transfer latch, among the latches.

14. The memory device of claim 13, wherein the page buffer controller is configured to move a value moved to the sensing latch, back to the input/output latch.

15. The memory device of claim 14, wherein the page buffer controller is configured to output a value moved back to the input/output latch.

16. The memory device of claim 15, wherein the page buffer controller is configured to determine a bit line as a masking fail column based on a result of comparing an output value with the masking bit.

17. The memory device of claim 16, wherein the page buffer controller is configured to determine a bit line as a masking pass column when the output value coincides with the masking bit.

18. The memory device of claim 16, wherein the page buffer controller is configured to determine a bit line as the masking fail column when the output value does not coincide with the masking bit.

19. A method of operating a memory device comprising a page buffer including an input/output latch, a transfer latch, and a sensing latch, the method comprising:
inputting a masking bit to the input/output latch;
moving a value input to the input/output latch, to the transfer latch;
moving the value, moved to the transfer latch, to the sensing latch;
moving the value moved to the sensing latch, back to the input/output latch;
outputting the value moved back to the input/output latch; and
determining a bit line coupled to the page buffer as a masking fail column, based on a result of comparing an output value with the masking bit.

20. The method of claim 19, wherein determining the bit line includes determining the bit line coupled to the page buffer as the masking fail column in response to a determination that the output value does not coincide with the masking bit.
